(19) United States
(12) Patent Application Publication
(10) Pub. No.: US 2026/0231837 A1
(43) Pub. Date: Aug. 6, 2026

(54) SEMICONDUCTOR APPARATUS AND METHOD FOR MANUFACTURING SEMICONDUCTOR APPARATUS

(71) Applicant: MITSUBISHI ELECTRIC CORPORATION, Tokyo (JP)

(72) Inventor: Yutaka YONEDA, Tokyo (JP)

(73) Assignee: MITSUBISHI ELECTRIC CORPORATION, Tokyo (JP)

(21) Appl. No.: 19/148,314

(22) PCT Filed: Apr. 6, 2023
(86) PCT No.: PCT/JP2023/014270

§ 371 Date: Jul. 15, 2025

(51) Int. Cl. H10W 90/00

(52) U.S. Cl. CPC H10W 90/401; H10W 90/701

(57) ABSTRACT

In the semiconductor apparatus of the present disclosure a stem has a through hole which extends from a main surface having a stem protruding portion to an opposite surface of the surface. A lead pin includes a lead pin protruding portion which passes through the through hole and protrudes on the same side as the stem protruding portion. In a joining block, a first surface is solder-joined to a bridging substrate, and a second surface is solder-joined to the lead pin protruding portion. The bridging substrate and the lead pin are electrically connected to each other via the joining block. The solder used for the solder joining has a melting point lower than that of the joining block.

### FIELD

The present disclosure relates to a semiconductor apparatus and a method for manufacturing the semiconductor apparatus.

### BACKGROUND

PTL 1 discloses a semiconductor apparatus as a package for mounting an electronic device, the semiconductor apparatus including a base that includes a wiring board having a first surface and a wiring pattern located on the first surface, a second surface intersecting the first surface, and a through hole opened in the second surface, a signal line that passes through the through hole and includes a protruding portion protruding from an opening of the through hole in the second surface, and a conductive joining material that joins the wiring pattern and the protruding portion of the signal line. It is configured so that the conductive joining material covers at least a root portion of the protruding portion on the opening side. This makes it possible to prevent the conductive joining material from being thickened, and to prevent a decrease in transmission characteristics of a signal in the joining portion due to a capacitance shortage.

### CITATION LIST

### SUMMARY

### Technical Problem

In the manufacture of the above-described semiconductor apparatus, it is necessary to apply the conductive joining material between the signal line and the wiring pattern, but it is difficult to apply the pasty conductive joining material to a desired position by a desired amount.

To solve the above-described problem, the present disclosure has a first object to provide a semiconductor apparatus in which a signal line and a wiring pattern can be electrically connected easily.

The present disclosure has a second object to provide a method for manufacturing a semiconductor apparatus in which a signal line and a wiring pattern can be electrically connected easily.

### Solution to Problem

A first aspect of the present disclosure is preferably a semiconductor apparatus comprising:
a semiconductor module;
a stem comprising a stem protruding portion on which the semiconductor module is mounted and which protrudes toward a same side as the semiconductor module, and a through hole which extends from a main surface having the stem protruding portion to an opposite surface of the surface;
a bridging substrate located on an upper surface of the stem protruding portion;
a lead pin including a lead pin protruding portion which passes through the through hole and protrudes on a same side as the stem protruding portion; and
a joining block, wherein
the joining block
has a first surface and a second surface,
the first surface is solder-joined to the bridging substrate, and the second surface is solder-joined to the lead pin protruding portion,
a solder used for the solder joining has a melting point lower than that of the joining block, and
the bridging substrate and the lead pin are electrically connected to each other via the joining block.

A second aspect of the present disclosure is preferably a method for manufacturing a semiconductor apparatus on which a semiconductor module is mounted, the method comprising:
a first supply step of supplying a first solder between an upper surface of a stem protruding portion included in a stem and a bridging substrate;
a step of melting the first solder;
a step of solidifying the first solder to join the stem protruding portion and the bridging substrate;
a step of mounting a joining block on an upper surface of the bridging substrate;
a second supply step of supplying a second solder between the joining block and a protruding portion of a lead pin;
a step of melting the second solder; and
a step of solidifying the second solder to join the bridging substrate and the protruding portion of the lead pin to the joining block and electrically connecting the bridging substrate and the lead pin via the joining block.

### Advantageous Effects of the Invention

According to the first and second aspects of the present disclosure, there can be provided a semiconductor apparatus in which a signal line and a wiring pattern can be electrically connected easily, and a method for manufacturing the same.

### BRIEF DESCRIPTION OF DRAWINGS

FIG. 1 is a top view illustrating a semiconductor apparatus according to a first embodiment of the present disclosure.

FIG. 2 is a cross-sectional view of a portion along A-A of the semiconductor apparatus in FIG. 1.

FIG. 3 is a diagram illustrating a configuration of a semiconductor apparatus according to a comparative example of the present disclosure, viewed from the same direction as FIG. 2.

FIG. 4 is a diagram illustrating the method for manufacturing the semiconductor apparatus according to the first embodiment of the present disclosure, and is a diagram as viewed from the same direction as that in FIG. 2.

FIG. 5 is a diagram illustrating the method for manufacturing the semiconductor apparatus according to the first embodiment of the present disclosure, and is a diagram as viewed from the same direction as that in FIG. 2.

FIG. 6 is a diagram illustrating the method for manufacturing the semiconductor apparatus according to the first embodiment of the present disclosure, and is a diagram as viewed from the same direction as that in FIG. 2.

FIG. 7 is a diagram illustrating the method for manufacturing the semiconductor apparatus according to the first embodiment of the present disclosure, and is a diagram as viewed from the same direction as that in FIG. 2.

FIG. 8 is a diagram illustrating the method for manufacturing the semiconductor apparatus according to the first embodiment of the present disclosure, and is a diagram as viewed from the same direction as that in FIG. 2.

FIG. 9 is a diagram illustrating a configuration of the semiconductor apparatus according to the first embodiment of the present disclosure, and is a diagram as viewed from the same direction as that in FIG. 2.

FIG. 10 is a diagram illustrating the configuration of a semiconductor apparatus according to a second embodiment of the present disclosure, viewed from the same direction as that in FIG. 2.

FIG. 11 is a diagram illustrating the configuration of the semiconductor apparatus according to the second embodiment of the present disclosure, viewed from the same direction as that in FIG. 1.

FIG. 12 is a diagram illustrating the configuration of the semiconductor apparatus according to the second embodiment of the present disclosure, viewed from the same

FIG. 13 is a diagram illustrating the configuration of the semiconductor apparatus according to the second embodiment of the present disclosure, which is a front view of the main surface of the stem.

FIG. 14 is a diagram illustrating the configuration of the semiconductor apparatus according to the second embodiment of the present disclosure, viewed from the same direction as that in FIG. 2.

FIG. 15 is a diagram illustrating the configuration of the semiconductor apparatus according to the second embodiment of the present disclosure, which is a front view of the main surface of the stem.

FIG. 16 is a diagram illustrating the configuration of a semiconductor apparatus according to a third embodiment of the present disclosure, viewed from the same direction as that in FIG. 2.

### DESCRIPTION OF EMBODIMENTS

A semiconductor apparatus and a method for manufacturing the semiconductor apparatus according to embodiments of the present disclosure will be described with reference to the drawings. Identical or corresponding constituent elements will be denoted by the same reference numerals, and the repeated description of such constituent elements may be omitted.

### First Embodiment

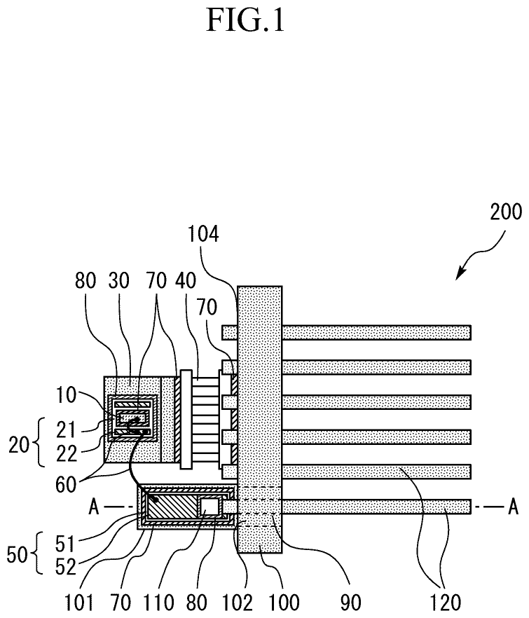

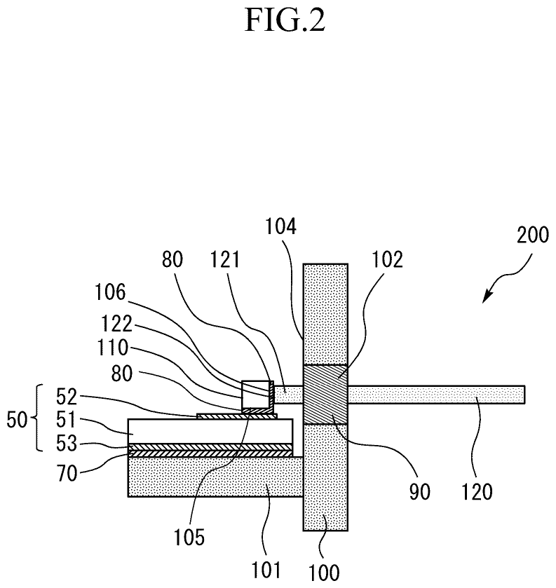

FIG. 1 is a top view illustrating a semiconductor apparatus 200 according to a first embodiment of the present disclosure. FIG. 2 is a cross-sectional view of a portion along A-A of the semiconductor apparatus 200 in FIG. 1. Note that FIGS. 1 and 2 each illustrate only a basic configuration portion in the semiconductor apparatus 200, but do not illustrate components such as a photo diode (PD), a thermistor, and a capacitor. Even when a constituent element is illustrated in any one of the top view and the cross-sectional view of the semiconductor apparatus 200, it may be unillustrated in the other figure when the description thereof is unnecessary. This point is common in all the embodiments described below.

The semiconductor apparatus 200 includes an optical semiconductor module 10, a submount 20, a carrier 30, a thermo-module 40, a bridging substrate 50 having a wiring pattern, a stem 100, and lead pins 120 serving as signal lines.

Hereinafter, surfaces illustrated in a top view in FIG. 1 are referred to as upper surfaces of the semiconductor apparatus 200 and components of the semiconductor apparatus 200. The opposite surfaces to the upper surfaces are referred to as back surfaces of the semiconductor apparatus 200 and components assembled as the semiconductor apparatus 200. Furthermore, surfaces viewed from a left side (right side) of the paper plane are referred to as left side surfaces (right side surfaces) of the semiconductor apparatus 200 and the components assembled as the semiconductor apparatus 200. This point is common in all the embodiments described below.

The submount 20 is a mounting base having the upper surface to which the optical semiconductor module 10 is joined by first solder 70. The carrier 30 is joined to the back surface of the submount 20 by second solder 80. The thermo-module 40 is joined to the right side surface of the submount 20 by the first solder 70.

The stem 100 is joined to the right side surface of the thermo-module 40 by the first solder 70.

A stem protruding portion 101 protruding toward the same side as the semiconductor module is formed on a main surface 104 of the stem 100. As illustrated in the cross-sectional view of FIG. 2, in a surface having the stem protruding portion 101, a through hole 102 which extends from the main surface 104 to an opposite surface is provided above the stem protruding portion 101.

The bridging substrate 50 is joined to the upper surface of the stem protruding portion 101 of the stem 100 by the first solder 70. A metal block 110 is joined, by the second solder 80, to the upper surface of the bridging substrate 50.

The right side surface of the metal block 110 is joined, by the second solder 80, with the lead pin 120 which passes through the through hole 102 of the stem 100.

Hereinafter, with continuing reference to FIGS. 1 and 2, each component will be described in more detail.

The optical semiconductor module 10 is a device that converts an electrical signal into an optical signal or converts an optical signal back into an electrical signal. A laser diode (LD), a photo diode (PD), and the like correspond to the optical semiconductor module 10. The optical semiconductor module 10 is made of materials such as InP, GaAs, GaN, InGaAs, Ge, and Si. An LD containing InP is suitable for the optical semiconductor module 10 of the present embodiment, but the type and material of the device are not limited. A pad portion is formed by Au metallization in the optical semiconductor module 10. The optical semiconductor module 10 and the submount 20 can be mechanically and electrically joined by the pad portion.

In the present embodiment, the number of optical semiconductor modules 10 is one, and, alternatively, a plurality of optical semiconductor modules 10 may be provided. In this case, a plurality of optical semiconductor modules 10 may be joined to a single submount 20. This point is common in all the embodiments described below.

The submount 20 includes a substrate 21, an electrode pad 22 formed on an upper surface or a back surface of the substrate 21, and an electrode pad 23 formed on a surface different from the electrode pad 22 of the upper surface and the back surface of the substrate 21. As materials of the substrate 21, an electric insulator and a material having high thermal conductivity to effectively cool the optical semiconductor module 10 are preferably used, and in general, a ceramic plate of AlN, Al2O3, or the like is used.

In the semiconductor apparatus 200 of the present embodiment, the number of submounts 20 is one, but the number of submounts 20 is not limited.

The same material is generally used for the electrode pad 22 and the electrode pad 23. The optical semiconductor module 10 is joined to the electrode pad 22 by the first solder 70. Furthermore, the electrode pad 22 is electrically connected to the peripheral member and the surface of the optical semiconductor module 10 by wires 60 or the like.

The electrode pad 22 is a wiring member for electrically connecting the optical semiconductor module 10 with an external circuit, and thus, the electrode pad 22 is preferably formed of metal with a small electric resistance. As the electrode pad 22 and the electrode pad 23, metallization with Au or the like with a thickness of 3.0 μm or thinner is generally used.

In the present embodiment, first, the electrode pad 22 made of Au and having a thickness of 1.5 μm is metalized on the substrate 21 made of AlN and having a thickness of 0.3 mm. Furthermore, in the electrode pad 22, the first solder 70 having a thickness of 3 μm and containing AuSn is pre-coated on a portion to which the optical semiconductor module 10 is joined. This makes it possible to obtain the electrode pad 22 suitable for the present embodiment.

The electrode pad 23 installed on a heat dissipation surface side of the substrate 21 is mechanically and thermally connected to the carrier 30 via solder, an Ag paste, or the like. In the present embodiment, the electrode pad 23 is connected to the carrier 30 by the second solder 80 of SnAgCu type.

For the carrier 30, a material having excellent thermal conductivity, such as metal such as Ag, Cu, Fe, or Al or an alloy thereof, and further, an insulator made of ceramic or resin which is covered with metal, is used. In the present embodiment, the carrier 30 in which Au plating is applied on the surface of CuW is preferably used, but not limited thereto.

The carrier 30 of the present embodiment has a protruding shape as viewed from above. Here, for the sake of description, a protruding part in the protruding shape is referred to as a protruding portion, and the other part in the protruding shape is referred to as a bottom portion. In the carrier 30, the thermo-module 40 is joined, by the first solder 70, to the right side surface of the bottom portion. On the other hand, the submount 20 is joined, by the second solder 80, to the upper surface of the protruding portion. For the joining, the second solder 80 of SnAgCu type is used. Furthermore, the optical semiconductor module 10 is joined on the upper surface of the submount 20. Note that the shape of the carrier 30 is not limited to the protruding shape, and may include the other shapes.

The thermo-module 40 releases the received heat to the stem 100 or the like via a peltier element. The thermo-module 40 controls the temperature of the optical semiconductor module 10, thereby making it possible to stably operate the optical semiconductor module 10. A metallization 41 is formed on a joined surface of the thermo-module 40 with the carrier 30, and a metallization 42 is formed on a joined surface of the thermo-module 40 with the stem 100. Note that the same material is generally used for the metallization 41 and the metallization 42. Au or the like having a thickness of about 3.0 μm is used as the metallization 41 and the metallization 42.

The bridging substrate 50 is joined, by the first solder 70, to the stem protruding portion 101 of the stem 100. The bridging substrate 50 includes a substrate 51, an electrode pad 52 formed on an upper surface of the substrate 51, and an electrode pad 53 formed on a back surface of the substrate 51. As materials of the substrate 51, an electric insulator is preferably used, and in general, a ceramic plate of AlN, Al2O3, or the like is used. The bridging substrate 50 drives the optical semiconductor module 10 by a high-frequency electric signal, or outputs a high-frequency signal output from the optical semiconductor module 10 to the lead pin 120 electrically connected via the metal block 110.

The same material is generally used for the electrode pad 52 and the electrode pad 53. The electrode pad 52 located on the circuit side of the bridging substrate 50 is joined, by the second solder 80, with the metal block 110. A joining portion such as a wire 60 is formed in the electrode pad 52, so that the electrode pad 52 is electrically connected with the electrode pad 22 of the submount 20 by the joining portion. The electrode pad 52 is a wiring member, and thus, the electrode pad 52 is preferably formed of metal with a small electric resistance similarly to the above-described electrode pad 22. As the electrode pad 52 and the electrode pad 53, metallization with Au or the like with a thickness of 3.0 μm or thinner is generally used. In the present embodiment, the bridging substrate 50 in which the electrode pad 52 made of Au and having a thickness of 1.0 μm is metalized on the substrate 51 made of Al2O3 and having a thickness of 0.5 mm is preferably used, but not limited thereto.

The electrode pad 53 is joined on the upper surface of the stem protruding portion 101. In the present embodiment, the first solder 70 is used for the joining, but the conductive joining material such as an Ag paste may be used for the joining.

For example, the wires 60 electrically connect between the electrode pad 52 formed on the upper surface of the bridging substrate 50 and the electrode pad 22 formed on the submount 20. The connection is performed by a method using, for example, an ultrasonic wave. Furthermore, the wires 60 are used to electrically connect between the stem protruding portion 101 and the carrier 30, between the bridging substrate 50 and the submount 20, and between the lead pins 120 except for the lead pin 120 joined to the metal block 110 and the thermo-module 40, and the like. Note that the connecting positions by the wires 60 are not limited thereto.

As the material of the wire 60, metal with a small electric resistance is preferably used. Therefore, metal such as Au, Cu or Al or an alloy thereof is generally used.

The first solder 70 is used for the joint between the electrode pad 22 of the submount 20 and the optical semiconductor module 10. Here, at the time of the step in which the joining is performed by the first solder 70, the step (referred to as a carrier-mount joining step) in which the submount 20 including the optical semiconductor module 10 is joined, by the second solder 80, to the upper surface of the carrier 30 has not been performed yet. From this viewpoint, the material of the first solder 70 preferably has a melting point higher than that of the second solder 80, and is preferably metal having high thermal conductivity. This makes it possible to prevent the first solder 70 from being melted again in the carrier-mount joining step. The joining position by the first solder 70 is not limited to between the electrode pad 22 of the submount 20 and the optical semiconductor module 10.

As the first solder 70, an alloy containing Au, Sn, Pb, Ag, Cu, Zn, Ni, Sb, In, Ge, Si, or the like and having a melting point less than 450° C. is generally used. As the first solder 70 of the present embodiment, an alloy mainly containing Au, Sn, Ge, Si, or the like and having a melting point equal to or greater than 250° C. is preferably used. Note that, a eutectic solder of Au and Sn is particularly preferred for the first solder 70 of the present embodiment, but not limited thereto.

The second solder 80 is used for the carrier-mount joining step, for example. As described above, at the time of the carrier-mount joining step, the optical semiconductor module 10 and the submount 20 have already been joined to each other by the first solder 70. Accordingly, the material of the second solder 80 preferably has a melting point lower than that of the first solder 70, and is preferably metal having high thermal conductivity.

As the second solder 80, an alloy containing Sn, Pb, Ag, Cu, Zn, Ni, Sb, Bi, In, Ge, or the like and having a melting point less than 450° C. is generally used. As the second solder 80 of the present embodiment, an alloy mainly containing Sn, Ag, Cu, or the like and having a melting point equal to or greater than 200° C. is preferably used. Note that, a solder containing Ag and Cu in Sn is particularly preferred for the second solder 80 of the present embodiment, but not limited thereto.

An application example of the first solder 70 and the second solder 80 described in the present embodiment is merely an example, and the second solder 80 may be applied to a position described as the first solder 70 in the drawings, or vice versa. Furthermore, the first solder 70 and the second solder 80 may be the same.

An insulating adhesive 90 bonds the lead pin 120 which passes through the through hole 102 provided in the stem 100 and an inner wall of the through hole 102. Here, considering that a lens cap is joined to the stem 100, and the interior of the lens cap is sealed in the final step, it is required to make consideration to prevent the bonded portion from being separated to cause the breakage of the air-tightness when the stem 100 and the thermo-module 40 are joined by the first solder 70, for example. From this viewpoint, the insulating adhesive 90 is preferably made of a material having high heat resistance and a small expansion and contraction ratio.

Since it is required to electrically insulate the stem 100 from the lead pins 120, the material of the insulating adhesive 90 is preferably an insulating material. The insulating adhesive 90 of the present embodiment is preferably made of glass, but not limited thereto.

The stem 100 is, for example, a cylindrical plate, and the stem protruding portion 101 protruding toward the same side as the semiconductor module is formed on the main surface 104 of the stem 100. As illustrated in the cross-sectional view of FIG. 2, in a surface having the stem protruding portion 101, a through hole 102 which extends from the main surface 104 to an opposite surface is provided above the stem protruding portion 101.

The stem protruding portion 101 is formed to protrude further toward the optical semiconductor module 10 side than the protruding portion of the lead pin 120. The stem protruding portion 101 may be formed by mechanically joining a member different from the stem 100 by the solder or the like, but the bridging substrate 50 is joined, by the first solder 70, on the upper surface of the stem protruding portion 101, and thus, the stem protruding portion 101 is preferably formed integrally with the stem 100. The stem 100 is formed by metalizing, with Au, the surface of the metal easy to process at low cost, for example. A SPC material (cold-rolled steel plate) is preferably used for the stem protruding portion 101 of the present embodiment, but not limited thereto.

For the metal block 110, a material having excellent electric conductivity, such as metal such as Ag, Cu, Fe, or Al or an alloy thereof, and further, a material in which an electric insulator made of ceramic or resin is covered with metal, is used. In the present embodiment, the metal block 110 in which Au plating is applied on the surface of the CuW block is preferably used, but not limited thereto. The bridging substrate 50 is joined, by the second solder 80, to the back surface of the metal block 110 via the electrode pad 52. The lead pin 120 is joined, by the second solder 80, to the right side surface of the metal block 110.

Hereinafter, a surface of the metal block 110 to be solder-joined to the bridging substrate 50 is referred to as a first surface 105, and a surface of the metal block 110 to be solder-joined to a lead pin protruding portion 121 is referred to as a second surface 106. Note that the first surface 105 and the second surface 106 need not be perpendicular to each other, and may be parallel to each other or may be the same surface.

The metal block 110 of the present embodiment preferably has a cubic or rectangular parallelepiped shape. However, the metal block 110 may have another shape.

The lead pin 120 is a signal line made of a material having excellent electric conductivity, such as metal such as Ag, Cu, Fe, Al, or Ni or an alloy thereof, and further, a material in which an insulator made of ceramic or resin is covered with metal. The lead pin 120 has a circular columnar or rectangular columnar shape. Note that the lead pin 120 of the present embodiment preferably has a circular columnar shape with a diameter of 0.3 mm and a length of 8 mm, in which Au plating is applied on the surface of Fe-50Ni, but not limited thereto.

As described above, one of the plurality of lead pins 120 has the lead pin protruding portion 121 that passes through the through hole 102 formed in the stem 100 and protrudes toward the same side as the stem protruding portion 101. Furthermore, the lead pin 120 is joined, by the second solder 80, to the metal block 110 in an end surface 122 of the lead pin protruding portion 121. However, the lead pin 120 need not be joined to the end surface 122 of the lead pin protruding portion 121, and may be joined to a side surface thereof. Note that in a case where two or more of the plurality of lead pins 120 are joined to the metal block 110, a plurality of through holes 102 may be provided, so that the respective lead pins 120 can pass through the plurality of through holes 102 and can be electrically connected with the metal block 110.

### Comparative Example

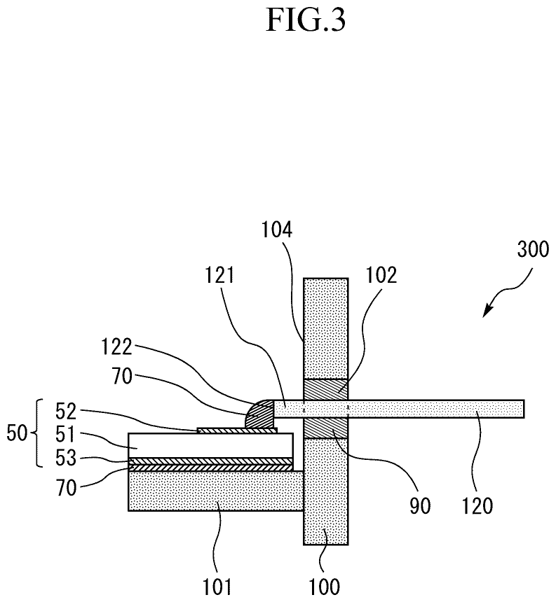

FIG. 3 is a diagram illustrating a configuration of a semiconductor apparatus 300 according to a comparative example of the present disclosure, viewed from the same direction as FIG. 2. As shown in FIG. 3, in a conventional semiconductor apparatus 300, the lead pins 120 and the electrode pad 52 are directly joined to each other by a conductive joining material such as the first solder 70. Since the lead pins 120 and the bridging substrate 50 are spaced apart from each other, the distance of the conductive joining material that bonds therebetween is increased.

Furthermore, since the lead pins 120 are fixed to the stem 100 by being bonded with the insulating adhesive 90, the positional deviation of the lead pin protruding portion 121 is large between individuals. In the conventional technology, when bonding the lead pins 120 to the bridging substrate 50, it is necessary to establish a manufacturing process that takes into account the amount of positional deviation.

### <Effects of the First Embodiment of the Present Disclosure>

On the other hand, as illustrated in FIG. 2, in the present embodiment, the lead pin 120 and the electrode pad 52 are joined to each other via the metal block 110. This makes it possible to increase a cross-sectional area when a current flows between the lead pin 120 and the bridging substrate 50, as compared to the conventional technique. As a result, this makes it possible to reduce the electric resistance between the lead pin 120 and the bridging substrate 50 as compared to the conventional technique, so that degradation of the transmission characteristics of the signal can be prevented. Furthermore, metal with a smaller electric resistance than the first solder 70 is used as the metal block 110, so that the above-described effects can be enhanced.

Furthermore, in the present embodiment, in the manufacture of the semiconductor apparatus 200, the upper surface of the metal block 110 which is not joined to both of the lead pin 120 and the electrode pad 52 is adsorbed by a collet, and can be easily mounted on a position contacting both of the end surface 122 of the lead pin 120 and the electrode pad 52. The use of the metal block 110 eliminates the need to manage an application portion and amount of the conductive joining material as in the conventional technique in which the lead pin 120 and the electrode pad 52 are directly joined by conductive joining, and enables simplification in manufacture.

Furthermore, in the present embodiment, an area of the surface of the metal block 110 joined with the lead pin 120 is larger than a positional shift amount of the lead pin protruding portion 121, so that the positional shift of the lead pin protruding portion 121 can be absorbed on the metal block 110 side. This eliminates the need to establish the manufacturing step reflecting the variation of the positional shift amount of the lead pin protruding portion 121 as in the conventional technique, and can contribute to the improvement in yield.

Hereinafter, a method for manufacturing the semiconductor apparatus 200 in the present embodiment will be described with reference to FIGS. 4 to 8. FIG. 4 is a diagram illustrating the method for manufacturing the semiconductor apparatus 200 according to the first embodiment of the present disclosure, and is a diagram as viewed from the same direction as that in FIG. 2. First, a plate-shaped first solder 70 is supplied to the upper surface of the stem protruding portion 101 formed in the stem 100 (first step).

Furthermore, the surface facing the main surface 104 of the stem 100 is heated by a heater 150 to thereby melt the first solder 70 (second step). Note that in the second step, a step of melting once the second solder 80 which is previously supplied to the end surface 122 of the lead pin 120 may be added.

Next, FIG. 5 is a diagram illustrating the method for manufacturing the semiconductor apparatus 200 according to the first embodiment of the present disclosure, and is a diagram as viewed from the same direction as that in FIG. 2. In a state in which the first solder 70 on the upper surface of the stem protruding portion 101 is melted, the bridging substrate 50 is mounted by a mounting device 160 (third step). Furthermore, the entire stem 100 is cooled to thereby solidify the first solder 70 (fourth step). This enables the stem protruding portion 101 and the bridging substrate 50 to be joined to each other. Note that the temperature of the heater 150 set to melt the first solder 70 is, for example, 360° C.

The third step and the fourth step may be executed before or after the step of joining the thermo-module 40 to the stem 100 by the first solder 70, but may be preferably executed before the step of joining.

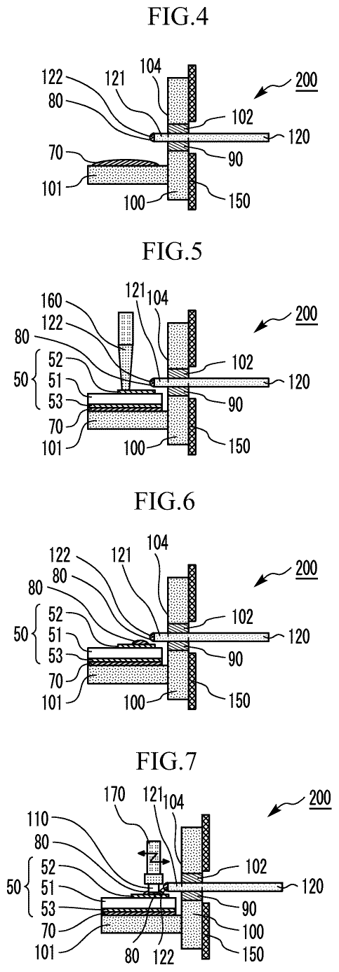

FIG. 6 is a diagram illustrating the method for manufacturing the semiconductor apparatus 200 according to the first embodiment of the present disclosure, and is a diagram as viewed from the same direction as that in FIG. 2. A plate-shaped second solder 80 is supplied onto the electrode pad 52 of the bridging substrate 50 and the surface facing the main surface 104 of the stem 100 is heated by the heater 150 to thereby melt the second solder 80 (fifth step).

FIG. 7 is a diagram illustrating the method for manufacturing the semiconductor apparatus 200 according to the first embodiment of the present disclosure, and is a diagram as viewed from the same direction as that in FIG. 2. In a state in which the second solder 80 on the electrode pad 52 is melted, the metal block 110 is mounted from above and the metal block 110 is scrubbed by a scrubbing machine 170 (sixth step). In the sixth step, the stem 100 is heated to thereby scrub the metal block 110 while heating via the bridging substrate 50. The scrubbing direction includes at least a longitudinal direction of the lead pin 120, so that the second solder 80 on the electrode pad 52 is also dispersed to the end surface 122 of the lead pin 120.

Note that in the second solder 80 supplied in the first step, an oxide film is present on the surface when melted. The oxide film can be removed by scrubbing the metal block 110. The use of a flux eliminates the need to scrub, but it is necessary to perform cleaning when the flux is attached to the peripheries after solder joining, and thus, it is preferable to perform scrubbing.

FIG. 8 is a diagram illustrating the method for manufacturing the semiconductor apparatus 200 according to the first embodiment of the present disclosure, and is a diagram as viewed from the same direction as that in FIG. 2. The stem 100 is heated in a state in which the metal block 110 is brought into contact with the end surface 122 of the lead pin 120 to thereby heat the lead pin 120 (seventh step). Finally, the entire stem 100 is cooled in a state in which the positions of the metal block 110 and the lead pin 120 are fixed to thereby solidify the second solder 80 (eighth step). This enables the metal block 110 to be joined to both of the electrode pad 52 and the lead pin 120. As a result, the bridging substrate 50 and the lead pin 120 can be electrically connected to each other via the metal block 110.

Note that in the sixth step, the oxide film formed on the surface of the second solder 80 can be removed, and thus, the sixth step and the seventh step are preferably performed simultaneously with the above-described carrier-mount joining step in terms of step simplification.

Note that the first solder 70 is changed to the second solder 80, so that the third step of joining the above-described bridging substrate 50 to the stem protruding portion 101 of the stem 100 can be also included in the carrier-mount joining step. However, in this case, the second solder 80 solidified in the third step is melted again in the sixth step, and thus, care will need to be taken to prevent the positional shift of the bridging substrate 50 while the metal block 110 is scrubbed. Note that the temperature of the heater 150 set to melt the second solder 80 is, for example, 300° C., but not limited

Here, in the conventional technique according to the comparative example illustrated in FIG. 3, the lead pin 120 is heated up to the temperature that allows the lead pin 120 to be solder-joined when the lead pin 120 and the bridging substrate 50 are solder-joined to each other, but at this time, the lead pin 120 is fixed to the stem 100 with the insulating adhesive 90. Therefore, in the conventional technique, it is necessary to effectively heat the stem 100 and heat the lead pin 120 via the insulating adhesive 90.

However, the thermal conductivity of the insulating adhesive 90 is smaller than that of the metal and the like, and thus, it is necessary to heat the stem 100 up to the temperature higher than the temperature at which the first solder 70 is normally melted or to heat the stem 100 over time longer than the time required for the first solder 70 to be normally melted.

On the other hand, in the present embodiment, the stem 100 is heated in a state in which the metal block 110 is brought into contact with the end surface 122 of the lead pin 120 in the seventh step, so that the lead pin 120 can be heated indirectly from the stem 100 via the bridging substrate 50. The bridging substrate 50 and the metal block 110 have the thermal conductivity generally larger than that of the insulating adhesive 90, so that the lead pin 120 can be heated at lower temperature and faster than the conventional technique in which the lead pin 120 is heated from the stem 100 via the insulating adhesive 90. This can shorten the time required to assemble the product.

In the conventional technique illustrated in FIG. 3, when the lead pin 120 and the bridging substrate 50 are joined to each other by the first solder 70, it is general to use the first solder 70 in which the surface is coated with Au or to perform the joining in a reduction atmosphere such as nitrogen for preventing oxidation of the first solder 70. In the conventional technique, it is difficult to use the second solder 80 which is oxidized more easily than the first solder 70, so that the first solder 70 having the melting point higher than the second solder 80 has to be used. When the lead pin 120 is heated, solder at other joined portions is also melted again, and thus, it is necessary to manage the temperature so that the positional shift of members at the joined portions is prevented, and the insulating adhesive 90 filled into the through hole 102 of the stem 100 is prevented from being separated to cause the breakage of the air-tightness.

On the other hand, in the present embodiment, the surface oxide film of the solder can be broken by scrubbing in the sixth step, and the second solder 80 which is oxidized easily can be used. This makes it possible to make the heating temperature lower than the conventional technique in which the first solder 70 is used, and thus, it becomes unnecessary to manage the temperature.

Note that the second solder 80 supplied in the fifth step has to have the melting point lower than the metal block 110 so that the metal block 110 is not melted during the heating. Even when the first solder 70 is used instead of the second solder 80, this point is also common. This point is also common in all the embodiments described below.

As described above, according to the present embodiment, there can be provided the semiconductor apparatus 200 in which the lead pin 120 serving as a signal line and the bridging substrate 50 serving as a wiring pattern can be electrically connected easily and the method for manufacturing the same.

### Modification Example

An example of the semiconductor apparatus 200 provided with the optical semiconductor module 10 has been described above, but the present invention can be applied to a power semiconductor apparatus and the like.

Note that the first step has been described in which the plate-shaped first solder 70 is supplied to the upper surface of the stem protruding portion 101 formed in the stem 100, but a method for supplying the first solder 70 is not limited thereto. For example, the first solder 70 may be previously applied to the electrode pad 53 of the bridging substrate.

Similarly, the description has been made in which in the fifth step, the plate-shaped second solder 80 is supplied onto the electrode pad 52 of the bridging substrate 50, and further in the sixth step, the metal block 110 is scrubbed and the second solder 80 is dispersed to the end surface 122 of the lead pin 120. However, the method of supplying the second solder 80 is not limited thereto. For example, the second solder 80 may be previously applied to the lead pin protruding portion 121. In this case, it becomes unnecessary to scrub the metal block 110 in the sixth step.

FIG. 9 is a diagram illustrating a configuration of the semiconductor apparatus 200 according to the first embodiment of the present disclosure, and is a diagram as viewed from the same direction as that in FIG. 2. In the metal block 110, the second solder 80 is applied on all the surfaces except for the upper surface, the surfaces being adsorbed by a collet for conveyance. The second solder 80 is previously applied to the metal block 110 by plating or the like, so that it becomes unnecessary to supply the second solder 80 to the bridging substrate 50 in the fifth step. Furthermore, in the sixth step, it becomes unnecessary to scrub the metal block 110 and disperse the second solder 80 to the end surface 122 of the lead pin 120.

Note that it is unnecessary to apply the second solder 80 to all the surfaces except for the upper surface as illustrated in FIG. 9, and the second solder 80 may be applied to the surface on the electrode pad 52 side of the metal block 110 and the surface on the lead pin 120 side. In addition, the second solder 80 for joining the metal block 110 and the lead pin 120 and the second solder 80 for joining the metal block 110 and the electrode pad 52 may be integrated with each other.

### Second Embodiment

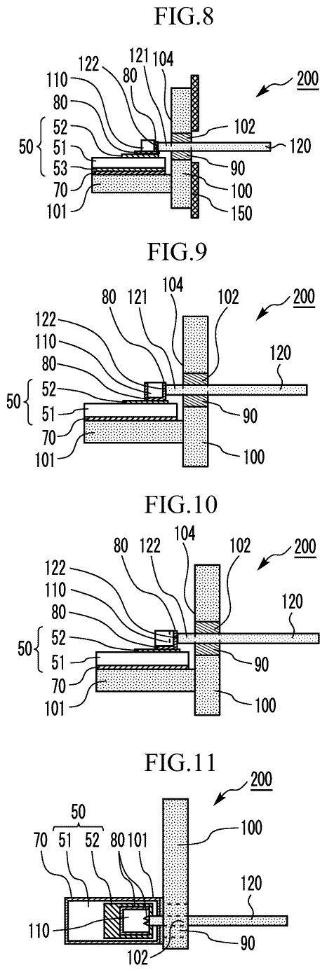

FIG. 10 is a diagram illustrating a configuration of a semiconductor apparatus 200 according to the second embodiment of the present disclosure, viewed from the same direction as in FIG. 2. FIG. 11 is a diagram illustrating a configuration of the semiconductor apparatus 200 according to the second embodiment of the present disclosure, viewed from the same direction as in FIG. 1. On the surface of the metal block 110 on the lead pin 120 side, one or more cutouts or recessed portions are formed in the vertical direction of the drawing. Accordingly, in the sixth step, when the second solder 80 on the bridging substrate 50 is melted, the molten second solder 80 climbs up into the cutout or recessed portion by capillary action, filling the inside and reaching between the metal block 110 and the lead pin 120. As a result, solder bonding can be achieved without supplying the second solder 80 directly to the lead pin 120.

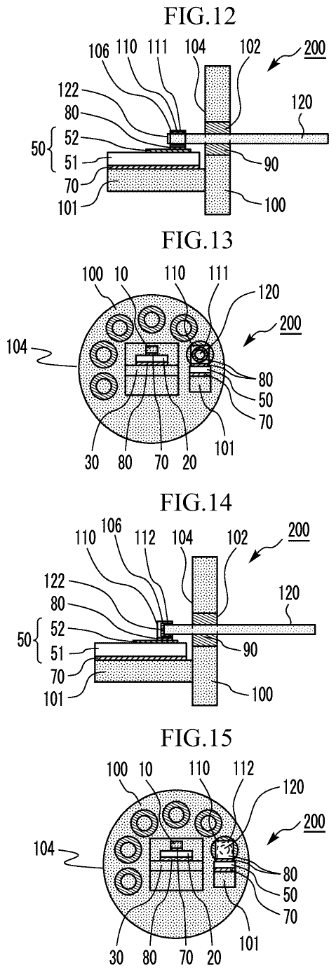

FIG. 12 is a diagram illustrating a configuration of the semiconductor apparatus 200 according to the second embodiment of the present disclosure, viewed from the same direction as in FIG. 2. FIG. 13 is a diagram illustrating a configuration of the semiconductor apparatus 200 according to the second embodiment of the present disclosure, showing a front view of the main surface 104 of the stem 100. The metal block 110 is provided with a block through-hole 111 penetrating from the surface on the lead pin 120 side in the extension direction of the lead pin 120. Further, the lead pin protruding portion 121 passes through the block through-hole 111 and is joined to the second surface 106 of the metal block 110 within the block through-hole 111 by the second solder 80. This increases the stability of the components during bonding and enables reliable solder bonding. Furthermore, since the bonding area between the lead pin 120 and the metal block 110 can be increased compared to the first embodiment, electrical resistance can be reduced and degradation of transmission characteristics can be suppressed.

The shape of the block through-hole 111 is not limited to a cylindrical shape. For example, the diameter of the surface of the metal block 110 on the lead pin 120 side may be made larger than that of the opposing surface, forming a tapered shape. This allows for tolerance adjustment of the lead pin 120 within the block through-hole 111, which is

FIG. 14 is a diagram illustrating a configuration of the semiconductor apparatus 200 according to the second embodiment of the present disclosure, viewed from the same direction as in FIG. 2. FIG. 15 is a diagram illustrating a configuration of the semiconductor apparatus 200 according to the second embodiment of the present disclosure, showing a front view of the main surface 104 of the stem 100. A recessed portion 112 is provided in the metal block 110 extending from the surface on the lead pin 120 side toward the opposing surface. The lead pin protruding portion 121 is inserted into the recessed portion 112 and is joined to the second surface 106 of the metal block 110 within the recessed portion 112 by the second solder 80. This provides effects similar to those described with reference to FIGS. 12 and 13.

The recessed portion 112 may also have a tapered shape in which the diameter of the opening side is larger than that of the opposing side. This allows for tolerance adjustment of the lead pin 120 within the recessed portion 112, which is preferable.

### Third Embodiment

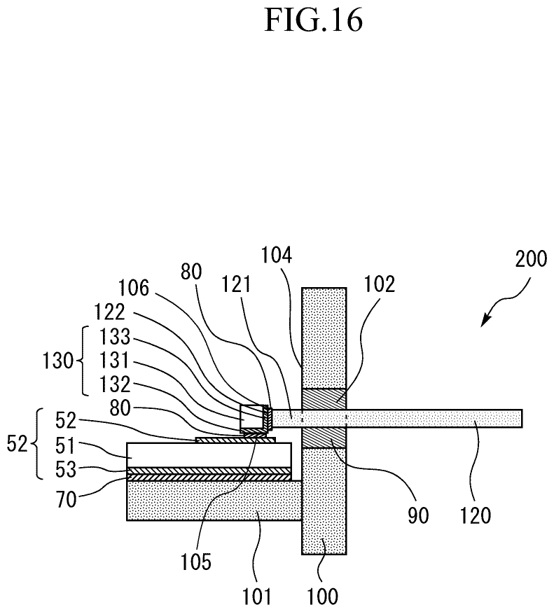

FIG. 16 is a diagram illustrating a configuration of the semiconductor apparatus 200 according to Third Embodiment of the present disclosure, viewed from the same direction as in FIG. 2. In the present embodiment, the metal block 110 described in first embodiment is replaced by a substrate 130.

The substrate 130 includes a base material 131, a first electrode pad 132 formed on the back surface of the base material 131, and a second electrode pad 133 formed on a surface perpendicular to the back surface of the base material 131. The base material 131 is an electrically insulating material, typically a ceramic plate such as AlN or Al₂O₃.

It is common to use the same material for both the first electrode pad 132 and the second electrode pad 133. The first electrode pad 132 is joined to the electrode pad 52 by the second solder 80. The surface on the first electrode pad 132 where this bonding occurs corresponds to the first surface 105 described in first embodiment.

The first electrode pad 132 and the second electrode pad 133 are electrically connected, for example, by metallizing the second electrode pad 133. Since the first electrode pad 132 serves as a wiring member that electrically connects the lead pin 120 and the electrode pad 52, it is preferably made of a metal having low electrical resistance. Metallization with a thickness of 3.0 μm or less using Au or the like is generally used for the first electrode pad 132 and second electrode pad 133. By forming the first electrode pad 132 and second electrode pad 133 in a state electrically connected via side surface metallization or the like, degradation in transmission characteristics between the lead pin 120 and the electrode pad 52 can be prevented.

In the present embodiment, a first electrode pad 132 composed of 3.0 μm thick Au is disposed on a base material 131 made of 0.5 mm thick AlN. Further, the second solder 80 containing 5 μm thick SnAgCu is pre-coated on the first electrode pad 132, and 0.1 μm thick Au is sputtered onto the surface of the second solder 80 to obtain a preferable substrate 130. However, the configuration of the substrate 130 is not limited to this

The second electrode pad 133 is joined to the end surface 122 of the lead pin 120 by the second solder 80. However, the bonding is not necessarily limited to the end surface 122 of the lead pin protruding portion 121 and may be performed on a side surface. The surface on the second electrode pad 133 on which this bonding is performed corresponds to the second surface 106 described in first embodiment.

For bonding, the second solder 80 having Au sputtered on its surface is preferable, as in the case of the first electrode pad 132. By pre-coating the second solder 80 with Au sputtering on the surfaces of both the first electrode pad 132 and the second electrode pad 133, surface oxidation of the second solder 80 can be prevented, and the step of supplying the second solder 80 can be omitted. Note that the second solder 80 with Au sputtered on its surface may also be pre-coated on both the surface of the metal block 110 on the bridging substrate 50 side and the surface on the lead pin 120 side as described in the first embodiment. This provides the same effects as described above.

When electrically connecting multiple lead pins 120 to the bridging substrate 50, in the first embodiment, a metal block 110 must be provided for each lead pin 120 to be joined. In contrast, in the present embodiment using the substrate 130, all lead pins 120 can be joined to the electrode pads 52 using a single substrate 130 by forming the first electrode pad 132 and second electrode pad 133 in accordance with the arrangement of the lead pins 120. This shortens the assembly time and suppresses increases in manufacturing cost. Note that this method is not limited thereto, and multiple substrates 130 may also be used to join multiple lead pins 120 to the bridging substrate 50.

In the present embodiment, the second electrode pad 133 is described as being formed on a surface perpendicular to the back surface of the base material 131.

However, the second electrode pad 133 may also be formed on the same surface as the first electrode pad 132, or on the top surface of the base material 131.

It should be noted that the present disclosure is not limited to the above-described embodiments and can be modified in various ways within the scope of the technical idea thereof. Moreover, the respective embodiments may be implemented in combination, in which case the combined effects can also be obtained.

### <Correspondence With Terms Used in Claims>

The metal block 110 described in first embodiment and the substrate 130 described in the second embodiment are referred to as a “joining block” in the claims.

### REFERENCE SIGNS LIST

10: optical semiconductor module, 20: submount, 21: substrate, 22: electrode pad, 23: electrode pad, 30: carrier, 40: thermo-module, 41: metallization, 42: metallization, 50: bridging substrate, 51: substrate, 52: electrode pad, 53: electrode pad, 60: wire, 70: first solder, 80: second solder, 90: insulating adhesive, 100: stem, 101: stem protruding portion, 102: through hole, 104: main surface, 105: first surface, 106: second surface, 110: metal block, 111: block through-hole, 112: recessed portion, 120: lead pin, 121: lead pin protruding portion, 122: end surface, 130: substrate, 131: base material, 132: first electrode pad, 133: second electrode pad, 150: heater, 160: mounting device, 170: scrubbing machine, 200: semiconductor apparatus, 300: conventional semiconductor apparatus,

1. A semiconductor apparatus, comprising:
a semiconductor module;
a stem comprising a stem protruding portion on which the semiconductor module is mounted and which protrudes toward a same side as the semiconductor module, and a through hole which extends from a main surface having the stem protruding portion to an opposite surface of the surface;
a bridging substrate located on an upper surface of the stem protruding portion;
a lead pin including a lead pin protruding portion which passes through the through hole and protrudes on a same side as the stem protruding portion; and
a joining block, wherein
the joining block
has a first surface and a second surface,
the first surface is solder-joined to the bridging substrate, and the second surface is solder-joined to the lead pin protruding portion,
a solder used for the solder joining has a melting point lower than that of the joining block, and
the bridging substrate and the lead pin are electrically connected to each other via the joining block.

2. The semiconductor apparatus according to claim 1, wherein
the joining block is made of metal or is a block in which an electric insulator is covered with metal.

3. The semiconductor apparatus according to claim 1, wherein
the joining block is a substrate comprising:
an insulating base material;
a first electrode pad formed on the base material; and
a second electrode pad electrically connected to the first electrode pad, wherein
in the first surface, the first electrode pad and the bridging substrate are solder-joined to each other, and
in the second surface, the second electrode pad and the lead pin protruding portion are solder-joined to each other.

4. The semiconductor apparatus according to claim 1, wherein
in the second surface, the joining block is joined to an end surface or a side surface of the lead pin protruding portion.

5. The semiconductor apparatus according to claim 1, wherein
a cutout or a recessed portion filled with the solder is further provided in the second surface of the joining block.

6. The semiconductor apparatus according to claim 1, wherein
the second surface of the joining block is an inner wall of a block through hole that extends in the joining block in an extending direction of the lead pin, and
the lead pin protruding portion passes through the block through hole, and is solder-joined to the joining block in the block through hole.

7. The semiconductor apparatus according to claim 1, wherein
the second surface of the joining block is an inner wall of a recessed portion included in the joining block, and
the lead pin protruding portion passes through an opening of the recessed portion, and is solder-joined to the joining block in the recessed portion.

8. The semiconductor apparatus according to claim 1, wherein
an electric resistance of the joining block is smaller than an electric resistance of the solder.

9. A method for manufacturing a semiconductor apparatus on which a semiconductor module is mounted, the method comprising:
a first supply step of supplying a first solder between an upper surface of a stem protruding portion included in a stem and a bridging substrate;
a step of melting the first solder;
a step of solidifying the first solder to join the stem protruding portion and the bridging substrate;
a step of mounting a joining block on an upper surface of the bridging substrate;
a second supply step of supplying a second solder between the joining block and a protruding portion of a lead pin;
a step of melting the second solder; and
a step of solidifying the second solder to join the bridging substrate and the protruding portion of the lead pin to the joining block and electrically connecting the bridging substrate and the lead pin via the joining block.

10. The method for manufacturing a semiconductor apparatus according to claim 9, wherein
a melting point of the first solder is higher than a melting point of the second solder.

11. The method for manufacturing a semiconductor apparatus according to claim 9, wherein
the first solder and the second solder are identical.

12. The method for manufacturing a semiconductor apparatus according to claim 9, wherein
the first supply step includes a step of supplying the first solder to an upper surface of the stem protruding portion.

13. The method for manufacturing a semiconductor apparatus according to claim 9, wherein
the second supply step includes:
a step of supplying the second solder to an upper surface of the bridging substrate; and
a step of scrubbing the joining block and dispersing the second solder supplied onto the bridging substrate between the joining block and the protruding portion of the lead pin.

14. The method for manufacturing a semiconductor apparatus according to claim 9, wherein
the second supply step includes a step of applying the second solder to the protruding portion of the lead pin.

15. The method for manufacturing a semiconductor apparatus according to claim 9, wherein
in the joining block, a surface to which the bridging substrate is to be joined serves as a first surface, and a surface to which the protruding portion of the lead pin is to be joined serves as a second surface, and
the second supply step includes a step of applying the second solder to a surface of the joining block including the first surface and the second surface.

16. The method for manufacturing a semiconductor apparatus according to claim 13, wherein
the second supply step further includes a step of sputtering Au on a surface of the supplied second solder.
